(19) United States
(12) Patent Application Publication
(10) Pub. No.: US 2011/0032014 A1
(43) Pub. Date: Feb. 10, 2011

(54) Delay locked loop circuit and signal delay method

(75) Inventors: Masahiko Shihara, Kanagawa (JP); Atsushi Tangoda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/801,894

(22) Filed: Jun. 30, 2010

(30) Foreign Application Priority Data
Aug. 4, 2009 (JP) 2009-181318

(51) Int. Cl. H03L 7/06

(52) U.S. Cl. 327/158

(57) ABSTRACT

A multiplier PLL multiplies a reference clock and outputs the multiplied clock. A DLL compares the clock output from the multiplier PLL with a clock obtained by delaying the clock output from the multiplier PLL. The DLL generates a delay signal having a given amount of delay based on the comparison result. A delay control signal operation circuit generates a delay control signal based on the delay signal generated by the DLL. A first delay circuit delays an input signal based on the delay control signal generated by the delay control signal operation circuit.

### INCORPORATION BY REFERENCE

This application is based upon and claims the benefit of priority from Japanese patent application No. 2009-181318, filed on Aug. 4, 2009, the disclosure of which is incorporated herein in its entirety by reference.

### BACKGROUND

1. Field of the Invention

The present invention relates to a delay locked loop circuit and a signal delay method.

2. Description of Related Art

When developing a new circuit, a DLL circuit adaptable to the circuit is required. In preparing the DLL circuit, many types of DLL circuits have to be formed into macros. Therefore, preparation of DLL circuits requires high development costs. For this reason, it is desirable that a DLL circuit be adaptable to a wide frequency band.

Japanese Unexamined Patent Application Publication No. 2007-124363 discloses a technology for a delay locked loop circuit forming a synchronous loop by delay elements. Japanese Unexamined Patent Application Publication No. 2007-124363 shows an example of the technology that supplies clocks to an LSI. FIG. 10 is a circuit diagram showing the delay locked loop circuit disclosed in Japanese Unexamined Patent Application Publication No. 2007-124363. The configuration and operation of the delay locked loop circuit described in Japanese Unexamined Patent Application Publication No. 2007-124363 will be explained as follows.

The delay locked loop circuit includes a first DLL part 50, a second DLL part 60, and an input signal delay part 70. A reference clock RCLK is supplied to the first DLL part 50. The first DLL part 50 is synchronous with the reference clock RCLK, and generates a phase delay signal DCTL1 having a given phase delay. The second DLL part 60 is supplied with a signal output from a phase interpolation circuit 45-1 and a zero-phase signal. The second DLL part 60 generates a phase delay signal DCTL2 that has the amount of delay between the zero-phase signal and the phase delay signal DCTL1. The input signal delay part 70 is supplied with an input signal IN and the phase delay signal DCTL2. The input signal delay part 70 applies a delay indicated by the phase delay signal DCTL2 to the input signal IN. The input signal delay part 70 outputs the delayed signal as an output signal OUT. The details of each component will be described below.

Here, the details of the first DLL part 50 will be described. A phase comparison circuit 52 compares a phase of a signal obtained by directly supplying the reference clock RCLK to the phase comparison circuit 52 with a phase of a signal obtained by causing the reference clock RCLK supplied to the first delay part 51 to pass through digital control delay circuits 51-1 to 51-12. The phase comparison is executed at edge timings, i.e., a signal rise timing and a signal fall timing.

A delay control circuit 53 sets, as a reference phase, the phase of the signal obtained by directly supplying the reference clock RCLK to the phase comparison circuit 52. The delay control circuit 53 controls the amount of delay of the digital control delay circuits 51-1 to 51-12 so that the signal obtained by causing the reference clock RCLK supplied to the first delay part to pass through the digital control delay circuits 51-1 to 51-12 has the same phase as the reference phase. The total amount of delay of the digital control delay circuits 51-1 to 51-12 equals the amount of delay corresponding to 360 degrees of a clock cycle of the reference clock RCLK. Output signals of the digital delay circuits 51-1 to 51-12 are supplied to the phase interpolation circuit 45-1 so as to generate a target amount of delay.

For example, assume that the target amount of delay is an arbitrary value (60+∂) in a range from 60 degrees to 120 degrees. In this case, each output of the digital control delay circuits 51-2, 51-3, and 51-4 is supplied to the phase interpolation circuit 45-1. The point where a phase signal is extracted from the first delay part varies depending on a desired target range of delay.

Here, the details of the second DLL part 60 will be described. The second DLL part 60 includes a second delay part 61, a phase comparison circuit 62, a delay control circuit 63, and a phase interpolation circuit 45-2. The phase interpolation circuit 45-2 is supplied with the reference clock RCLK. The phase interpolation circuit 45-2 is configured to output a zero-phase signal. That is, the phase interpolation circuit 45-2 generates its own fixed delay that is not controlled by a phase interpolation control signal. Hence, the phase interpolation circuit 45-2 outputs a signal that has the fixed delay to the second delay part 61.

The second delay part 61 includes a digital control delay circuit 51-14. The digital control delay circuit 51-14 receives a signal from the phase interpolation circuit 45-2, and applies a delay controlled by the delay control signal DCTL2 to the signal. The digital control delay circuit 51-14 outputs the delayed signal to the phase comparison circuit 62.

The phase comparison circuit 62 compares a phase of a signal delayed by the second delay part 61 with a signal that has an amount of delay set by the first DLL part 50. The phase comparison circuit 62 outputs the phase comparison result to the delay control circuit 63.

The delay control circuit 63 includes a charge pump and a filter. The delay control circuit 63 generates the delay control signal DCTL2 so that two signals supplied to the phase comparison circuit 62 have the same phase. The delay control circuit 63 outputs the generated delay control signal DCTL2 to the digital control delay circuit 51-14 and a digital control circuit 51-15 provided in a third delay part 71. The delay control signal DCTL2 is an n-bit signal. The amount of delay of the digital control delay circuit 51-14 is controlled by the delay control signal DCTL2. Because of the above feedback control, the second delay part 61 has an accurate amount of delay corresponding to a phase difference between two signals output from the first DLL part 50, i.e., a phase difference between a zero-phase signal and a target phase signal to be set.

Next, the details of the input signal delay part 70 will be described. The input signal delay part 70 includes the third delay part 71. The third delay part 71 includes the digital control delay circuit 51-15. The third delay part 71 has the same configuration as the second delay part 61 provided in the second DLL part 60. The amount of delay of the digital control delay circuit 51-15 is controlled by the delay control signal DCTL2. Accordingly, the amount of delay of the third delay part 71 equals the amount of delay of the second delay part 61. That is, the input signal delay part 70 delays the input signal IN by an amount of delay generated by the second DLL part 60. The input signal delay part 70 outputs the delayed signal as the output signal OUT.

### SUMMARY

The present inventors have found a problem that the delay locked loop circuit disclosed in Japanese Unexamined Patent Application Publication No. 2607-124363 may cause an increase in circuit area. The problem is described in detail below.

The delay control circuit 63 needs to perform control so that the reference clock RCLK has the same phase as the clock obtained such that the reference clock RCLK is supplied to the first delay part 51 and is further supplied to the phase comparison circuit 52 through the digital control delay circuits 51-1 to 51-12. Here, the amount of delay required to control the clock to have the same phase as the reference clock RCLK is a 360-degree phase of the reference clock RCLK. Therefore, the digital control delay circuits 51-1 to 51-12 in the first DLL part 50 need to have a maximum amount of delay corresponding to the 360-degree phase of the reference clock RCLK.

When the reference clock RCLK has a low-speed frequency, the clock cycle is long. As the clock cycle becomes long, the value of the delay corresponding to the 360-degree phase according to the clock cycle becomes large. When the delay locked loop circuit disclosed in Japanese Unexamined Patent Application Publication No. 2007-124363 is adapted to the reference clock RCLK that has a low-speed frequency, the amount of delay of the digital control delay circuits 51-1 to 51-12 is large. Therefore, the increase in amount of delay of the first DLL circuit 50 is also large.

Meanwhile, when the reference clock RCLK has a high-speed frequency, the clock cycle is short. Because the clock cycle is short, the first DLL circuit 50 needs to perform control so as to reduce an error rate with respect to the clock cycle of the reference clock RCLK. Therefore, it is necessary to reduce the resolution of delay steps of the digital control delay circuits 51-1 to 51-12. Because the resolution is small, the first DLL circuit 50 needs many delay steps.

That is, when the first DLL circuit 50 in the delay locked loop circuit disclosed in Japanese Unexamined Patent Application Publication No. 2007-124363 is adapted to a wide frequency range including a low-frequency range and a high-frequency range, the digital control delay circuits 51-1 to 51-12 need to have a large amount of delay corresponding to the low-frequency range. Also, the digital control delay circuits 51-1 to 51-12 need to have many delay steps corresponding to the high-frequency range. As a result, a DLL circuit area becomes large.

The details of the problem will be described with reference to FIGS. 10 and 11. FIG. 11 is a diagram showing a basic configuration of a general delay circuit used as the digital control delay circuits 51-1 to 51-12.

The input signal IN passes through delay elements 81-1 to 81-n and is output as the output signal OUT. Here, a selector 80 selects the number of steps of the delay elements 81-1 to 81-n through which the signal passes, based on a delay control signal DCTL. The number of steps of the delay elements 81-1 to 81-n through which the signal passes corresponds to the number of delay steps.

When the DLL circuit using the delay circuit (FIG. 11) as disclosed in Japanese Unexamined Patent Application Publication No. 2007-124363 is adapted to a reference clock that has a high-frequency band, the amount of delay is small. This is because the clock cycle of the reference clock is short. However, it is necessary to increase the number of the delay steps included in the digital control delay circuits 51-1 to 51-12 in order to decrease the resolution of the delay steps.

By contrast, when the DLL circuit using the delay circuit (FIG. 11) as disclosed in Japanese Unexamined Patent Application Publication No. 2007-124363 is adapted to the reference clock that has a low-frequency band, there is no need to decrease the resolution of the delay steps, since the clock cycle of the reference clock is long. However, the amount of delay which should be included in the DLL circuit is large.

As described above, when the DLL circuit disclosed in Japanese Unexamined Patent Application Publication No. 2007-124363 is adapted to the reference clock that has a high-frequency range and a low-frequency range, it is necessary to increase the number of delay steps and the amount of delay. Therefore, the area of the delay circuit shown in FIG. 11 is increased. As the area of the delay circuit shown in FIG. 11 increases, the digital control delay circuits 51-1 to 51-12 need to have a larger area. As a result, the area of the first DLL part 50 is increased.

A first exemplary aspect of the present invention is a delay locked loop circuit including a multiplier PLL (Phase Lock Loop) that multiplies a reference clock and outputs the multiplied reference clock, a DLL (Delay Locked Loop) that applies an amount of delay corresponding to a given cycle to the clock output from the multiplier PLL to generate a delay signal having a given amount of delay based on the amount of delay corresponding to the given cycle so that the delay signal has the same phase as the clock output from the multiplier PLL, a delay control signal operation circuit that generates a delay control signal having a given amount of delay based on the delay signal having the given amount of delay, and a first delay circuit that delays an input signal based on the delay control signal.

The delay locked loop circuit according to the first exemplary aspect of the invention can calculate a given amount of delay based on an amount of delay of an arbitrary cycle of the clock signal multiplied by the multiplier PLL. The delay locked loop circuit can generates a delay control signal to delay an input signal by a given amount of delay by performing an operation on the signal that has the given amount of delay. Also, the delay locked loop circuit can reduce an amount of delay in the DLL by multiplying the reference clock. This results in a reduction in the area of circuit compared to the circuit configuration disclosed in Japanese Unexamined Patent Application Publication No. 2007-124363.

The present invention can provide a delay locked loop circuit without increasing the circuit area.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing an exemplary configuration of a delay locked loop circuit according to a first exemplary embodiment of the present invention;

FIG. 2 is a timing chart showing a phase relationship between signals according to the first exemplary embodiment of the present invention;

FIG. 3 is a timing chart showing a phase relationship between an input signal IN and an output signal OUT according to the first exemplary embodiment of the present invention;

FIG. 4 is a block diagram showing an exemplary configuration of a delay locked loop circuit according to a second exemplary embodiment of the present invention;

FIG. 5 is a timing chart showing a phase relationship between signals according to the second exemplary embodiment of the present invention;

FIG. 6 is a timing chart showing a phase relationship between the input signal IN and the output signal OUT according to the second exemplary embodiment of the present invention;

FIG. 7 is a block diagram showing an exemplary configuration of a delay locked loop circuit according to a third exemplary embodiment of the present invention;

FIG. 8 is a timing chart showing a process of generating a select signal SEL according to the third exemplary embodiment of the present invention;

FIG. 9 is a block diagram showing an exemplary configuration of a delay locked loop circuit according to a fourth exemplary embodiment of the present invention;

FIG. 10 is a block diagram showing an exemplary configuration of a delay locked loop circuit according to the related art; and

FIG. 11 is a block diagram showing an exemplary configuration of a general digital control delay circuit.

### DETAILED DESCRIPTION OF THE EXEMPLARY EMBODIMENTS

### First Exemplary Embodiment

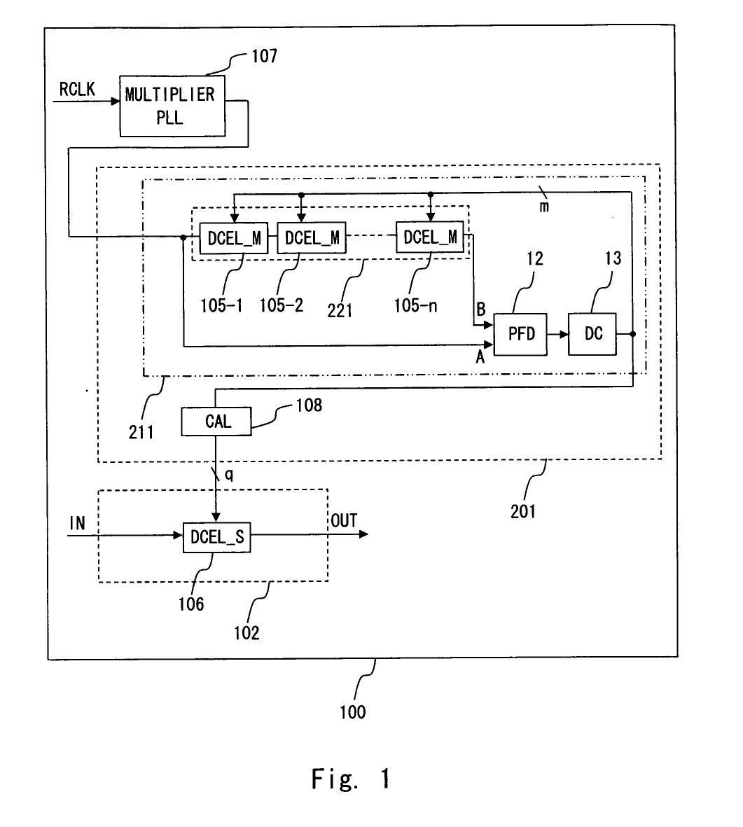

Now, exemplary embodiments of the present invention will be described with reference to the accompanying drawings. First, referring to FIG. 1, the basic configuration of a delay locked loop circuit according to a first exemplary embodiment of the present invention will be described. An LSI chip 100 includes a multiplier PLL (phase locked loop) 107, a master DLL circuit 201, and a slave delay circuit 102.

The multiplier PLL 107 is supplied with a reference clock RCLK. The multiplier PLL 107 multiplies a frequency of the reference clock RCLK by n to thereby generate a clock signal. The multiplier PLL 107 outputs the generated clock signal to the master DLL circuit 201. The multiplier PLL 107 is a generic PLL (Phase Locked Loop) that has a function of multiplying a clock signal.

The master DLL circuit 201 includes a DLL 211 (hereafter also referred to as a “master DLL part 211”), and a delay control signal operation circuit 108. The master DLL part 211 is supplied with the clock signal multiplied by the multiplied PLL 107. The master DLL part 211 includes a master delay part 221, a phase comparison circuit 12, and a delay control circuit 13.

The master delay part 221 (hereafter also referred to as a “second delay circuit”) has an arbitrary number of digital control delay circuits 105-1 to 105-n required for delay adjustment. The master delay part 221 is supplied with the clock signal multiplied by the multiplier PLL 107. The master delay part 221 outputs a comparison signal B to the phase comparison clock circuit 12.

The phase comparison circuit 12 is supplied with a comparison clock signal A multiplied by the multiplier PLL 107, and with a comparison signal B. The phase comparison circuit 12 compares a phase of the comparison signal A with a phase of the comparison signal B. The phase comparison circuit 12 outputs the phase comparison result to the delay control circuit 13.

The delay control circuit 13 controls a signal delay based on the phase comparison result output from the phase comparison circuit 12. The delay control circuit 13 outputs a delay control signal m to digital control delay circuits 105-1 to 105-n and a delay control signal operation circuit 108.

The delay control signal operation circuit 108 performs an operation based on the delay control signal m output from the master DLL 211. The delay control signal operation circuit 108 outputs a digital delay control signal q as an operation result to the slave delay circuit 102.

A first delay circuit 102 (hereafter also referred to as “slave delay circuit 102”) includes a digital control delay circuit 106. The slave delay circuit 102 is supplied with an input signal IN and the digital delay control signal q. The digital control delay circuit 106 includes a different number of stages of delay elements similar to the digital control delay circuits 105-1 to 105-n. The digital control delay circuit 106 delays the input signal IN based on the digital delay control signal q, and outputs the delayed signal OUT as an output signal to other circuits (not shown). When the delay control signal q, which has a delay amount in the range of the number of stages of the delay elements included in the digital control delay circuit 105-1 to 105-n and the digital control delay circuit 106, is supplied to the digital control delay circuit 106, the number of stages of the delay elements through which the signal passes is the same as that of the digital control delay circuits 105-1 to 105-n and the digital control delay circuit 106. Also, the amounts of delay thereof become equal.

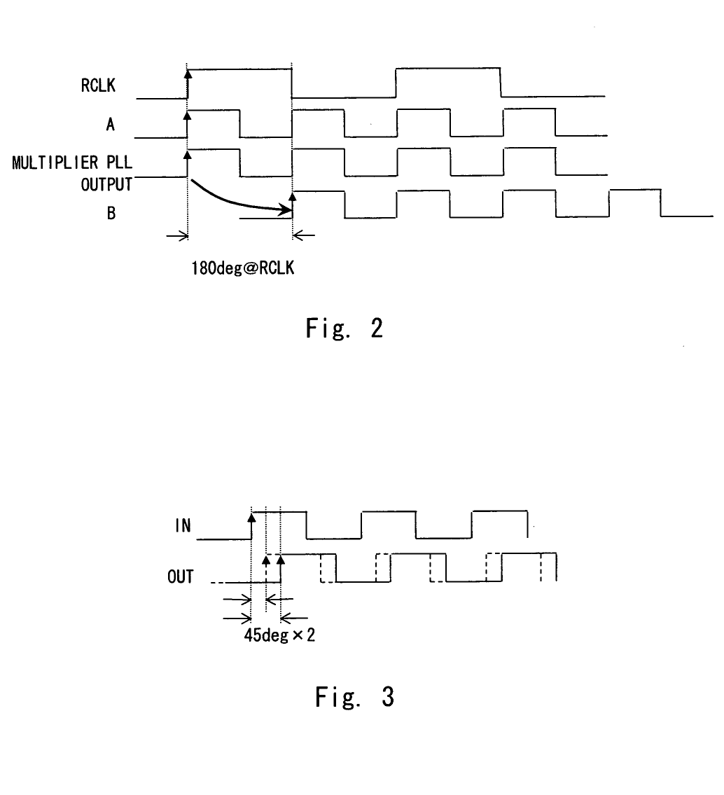

Next, description is given of the processing of the delay locked loop circuit of the first exemplary embodiment of the present invention when the multiplier PLL 107 multiplies a clock by 2. FIG. 2 shows a timing chart illustrating signals when the multiplier PLL 107 multiplies the clock by 2. FIG. 2 shows phase relationships between the reference clock RCLK, the comparison clock signal A of the phase comparison circuit 12, the clock output signal of the multiplier PLL 107, and the comparison signal B of the phase comparison circuit 12.

The multiplier PLL 107 outputs the clock which is twice as fast as the reference clock RCLK. The phase of the comparison clock signal A equals the phase of the clock which is twice as fast as the reference clock RCLK. A comparison clock signal B supplied to the phase comparison circuit 12 through the master delay part 221 has a 180-degree phase difference with respect to the reference clock RCLK because of the delay control.

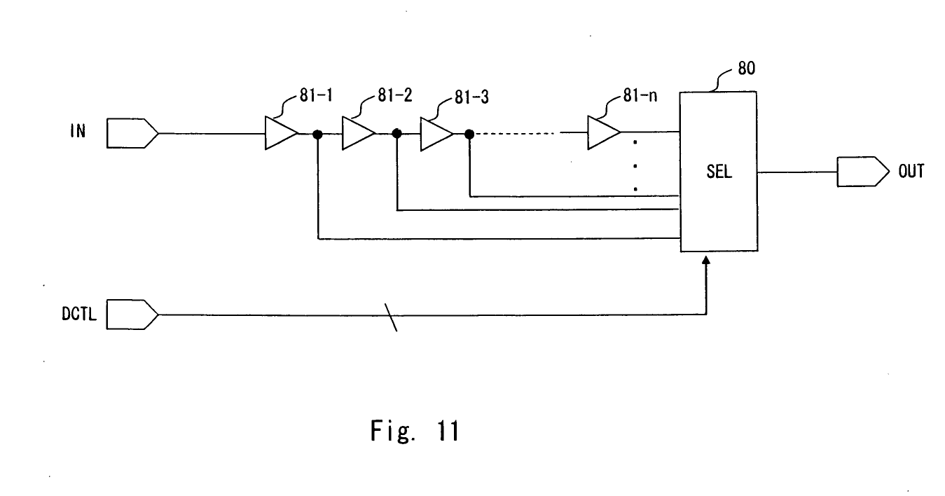

The delay control circuit 13 controls the amount of delay of the digital control delay circuits 105-1 to 105-n based on the phase comparison result of the phase comparison circuit 12. This control makes the phase of the comparison clock signal B equal to the phase of the comparison clock signal A. The digital control delay circuits 105-1 to 105-n have a configuration shown in FIG. 11.

The digital control delay circuits 105-1 to 105-n have an amount of delay corresponding to the 180-degree phase of the reference clock RCLK at a maximum so as to control the comparison signal clock B and the comparison clock signal A to have the same phase, by using the delay control signal m from the delay control circuit 13.

The case where the master delay part 221 consists of four digital control delay circuits (105-1 to 105-4) will be described. The amount of delay of each digital control delay circuit (105-1 to 105-4) corresponds to the 45-degree phase of the reference clock RCLK. Therefore, the delay control circuit 13 supplies the delay control signal m, which corresponds to the amount of delay of the 45-degree phase, to the digital control delay circuits 105-1 to 105-4. This enables the master delay part 221 to control a delay corresponding to the 180-degree phase of the reference clock RCLK.

The delay control signal operation circuit 108 performs an operation on the delay control signal m that has the amount of delay corresponding to the 45-degree phase of the reference clock RCLK to have a given phase. The delay control signal operation circuit 108 outputs the operation result as the digital control signal q to the slave delay circuit 102.

For example, assume that the input signal IN of the slave delay circuit 102 is delayed by the 90-degree phase of the reference clock RCLK and that the delayed signal is output as the output signal OUT. In this case, the delay control signal operation circuit 108 converts the delay control signal m, which corresponds to the amount of delay corresponding to the 45-degree phase of the reference clock RCLK, to a signal having the amount of delay corresponding to the 90-degree phase of the reference clock RCLK. That is, the delay control signal operation circuit 108 multiplies the delay control signal m by 2. The delay control signal operation circuit 108 supplies the generated digital delay control signal q to the slave delay circuit 102. Because of the digital delay control signal q, the output signal that has the amount of delay corresponding to the 90-degree phase of the reference clock RCLK with respect to the input signal IN of the slave delay circuit 102 can be generated as shown in the timing chart in FIG. 3. In addition, the delay control signal operation circuit 108 can be easily configured using general multipliers and so on.

Next, advantageous effects of the delay locked loop circuit according to this exemplary embodiment will be described.

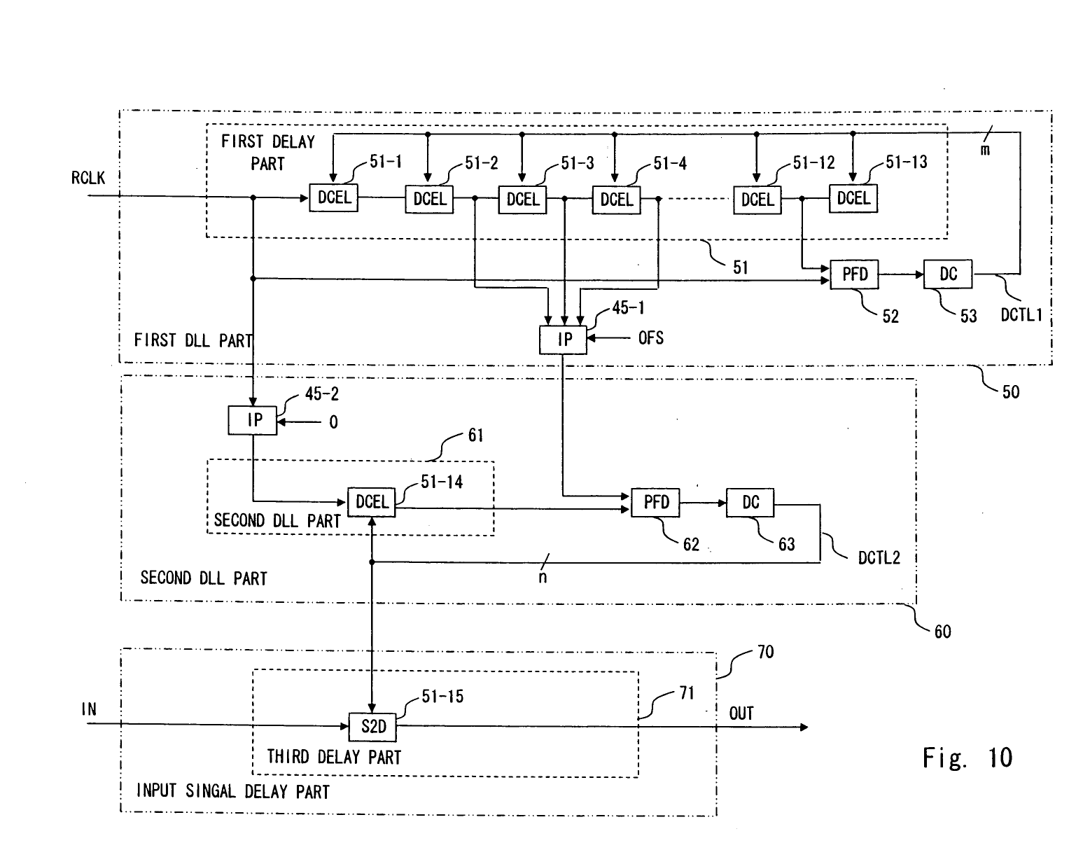

In the delay locked loop circuit disclosed in Japanese Unexamined Patent Application Publication No. 2007-124363, the digital control delay circuits 51-1 to 51-n shown in FIG. 10 need to generate the amount of delay corresponding to the 360-degree phase of the reference clock RCLK. This is because the delay control circuit 53 controls the amount of delay of the digital control delay circuits 51-1 to 51-12 so that the reference clock RCLK has the same phase as the delayed signal.

By contrast, in the delay locked loop circuit according to this exemplary embodiment, the multiplier PLL 107 multiplies the reference clock RCLK. The delay control circuit 13 in the delay locked loop circuit generates a delay signal based on a comparison result between a phase of the multiplied clock signal and a phase of the delayed multiplied clock signal. The delay control circuit 13 controls the two signals to have the same phase. By controlling the two signals to have the same phase, the amount of delay in the master DLL 201 reaches a given amount of delay corresponding to an arbitrary cycle of the multiplied clock. By multiplying (by n) the reference clock RCLK before being input to the master DLL circuit 201, the amount of delay that should be included in the master DLL circuit 201 can be set to 1/n of the 360-degree phase of the clock cycle of the reference clock RCLK. That is, the amount of delay in the master DLL circuit 201 can be reduced.

For example, when the multiplier PLL 107 multiplies the clock by 2 (n=2), the amount of delay that should be included in the master DLL circuit 201 may equal the amount of delay of the 180-degree (360/2) phase of the reference clock RCLK. That is, the digital control delay circuits 105-1 to 105-n may generate the amount of delay corresponding to the 180-degree phase of the reference clock RCLK.

By setting the amount of delay in the master delay circuit 201 to 1/n, the number of the delay elements in the master DLL circuit 201 can also be set to 1/n. That is, the number of the delay elements 81-1 to 81-n configuring the digital control delay circuits 105-1 to 105-n can be set to 1/n compared to the related art. This prevents an increase in the area of the DLL circuit.

The delay control signal operation circuit 108 performs an operation such that the delay control signal m output by the delay control circuit 13 has a given amount of delay. The delay control signal operation circuit 108 outputs the operation result as the digital delay control signal q to the slave delay circuit 102. The slave delay circuit 102 (the first delay circuit) delays the input signal IN based on the digital delay control signal q. Further, the slave delay circuit 102 outputs the delayed signal as the output signal OUT. That is, the output signal OUT can be generated by applying a given amount of delay to the input signal IN.

As noted above, the multiplying (by n) process by the multiplier PLL 107 prevents an increase in the area of the DLL circuit by the multiplying process. Therefore, the problem of increasing the area of the DLL circuit so as to be adapted to the high-frequency band and the low-frequency band of the reference clock RCLK can be resolved. Also, the multiplying process for the reference clock RCLK can be implemented using a normal multiplier PLL on a normal LSI chip. That is, the advantageous effects noted above are achieved using a configuration of a normal LSI chip.

### Second Exemplary Embodiment

A delay locked loop circuit according to a second exemplary embodiment the present invention is characterized by selecting whether to perform a process of generating an amount of delay including a multiplying process, or not using a selection signal.

When the reference clock RLCK has a high-speed frequency, the clock cycle is short. This makes it necessary to make an adjustment to reduce the amount of phase errors. Generally, in the case of delaying a signal by a digital control delay circuit, quantization errors occur depending on the resolution of delay steps. Therefore, in the configuration of the first exemplary embodiment, when the amount of delay controlled by the delay control signal operation circuit 108 is increased, the phase errors caused by the quantization errors also increase. For example, when the delay control signal m is multiplied by 2 by the delay control signal operation circuit 108, the phase errors caused by the quantization errors are doubled.

When the reference clock RLCK has a low-speed frequency, the clock cycle is long. Because the clock cycle is long, the tolerable amount of phase errors is relatively large. By contrast, when the reference clock RCLK has a high-speed frequency, the clock cycle is short. Because the clock cycle is short, the tolerable amount of phase errors is small. Therefore, the tolerable amount of phase errors needs to be adjusted based on the frequency of the reference clock RCLK. The delay locked loop circuit of this exemplary embodiment is configured by taking the phase errors into consideration. The delay locked loop circuit of this exemplary embodiment is described in detail below.

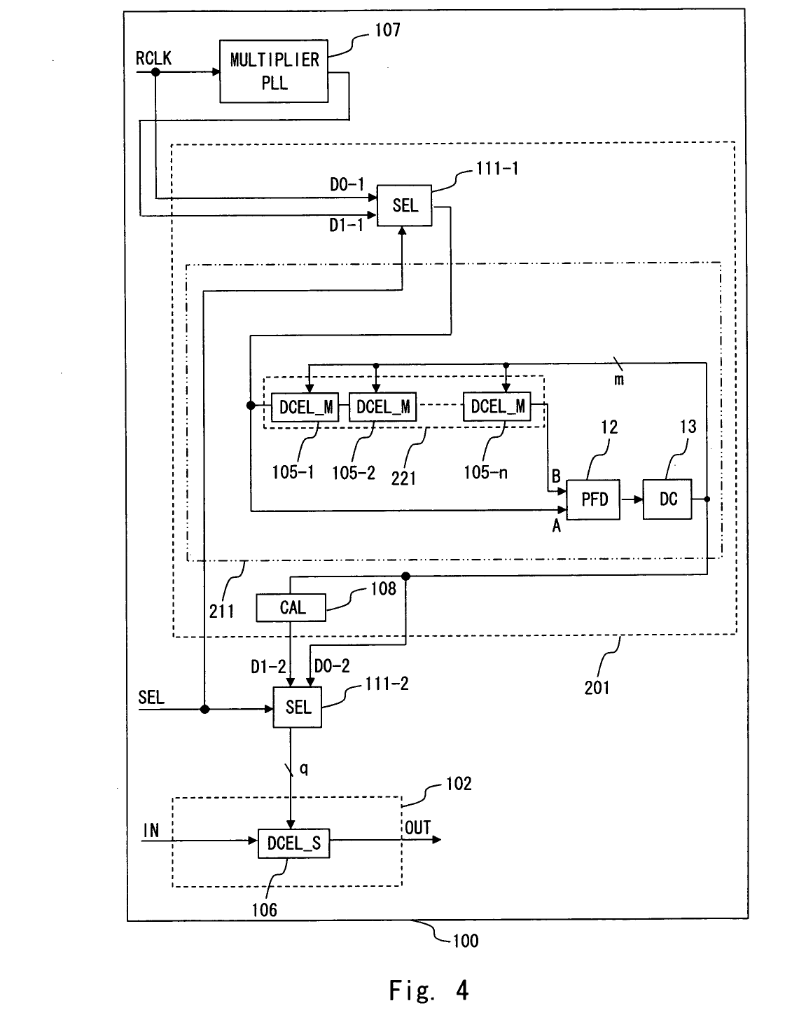

FIG. 4 is a block diagram showing the configuration of the delay locked loop circuit according to this exemplary embodiment. The LSI chip 100 includes the multiplier PLL 107, a first selection part 111-1 (hereafter also referred to as “SEL 111-1”), the master DLL circuit 201, a second selection part 111-2 (hereafter also referred to as “SEL 111-2”), and the slave delay circuit 102.

The multiplier PLL 107 multiplies the reference clock RCLK and outputs the multiplied clock to the SEL 111-1.

The reference clock RCLK (D0-1) and a signal (D1-1) output from the multiplier PLL 107 are input to the SEL 111-1. The SEL 111-1 selects one of the reference clock (D0-1) and the signal (D1-1) output from the multiplier PLL 107 based on the selection signal SEL. The SEL 111-1 outputs the selected signal to the master DLL 201. The detail of the selection signal SEL is described below.

The signal output by the SEL 111-1 is input to the master DLL 201. The master DLL 201 includes the master DLL part 211 and the delay control signal operation circuit 108. The master DLL part 211 includes the master delay part 221, the phase comparison circuit 12, and the delay control circuit 13. The master delay part 221 has the same configuration as the first exemplary embodiments. The phase comparison circuit 12 compares a phase of the comparison clock signal A output from the SEL 111-1 with the phase of a comparison clock signal B output from the master delay part 221. The delay control circuit 13 controls the amount of delay of the digital control delay circuits 105-1 to 105-n based on the comparison result of the phase comparison circuit 12. The delay control circuit 13 outputs the delay control signal m to the digital control delay circuits 105-1 to 105-n, the delay control signal operation circuit 108, and the SEL 111-2.

The delay control signal operation circuit 108 performs an operation on the delay control signal m, which is output from the master DLL part 211, to have a given delay. The delay control signal operation circuit 108 outputs the operation result as a signal D1-2 to the SEL 111-2.

A signal D0-2 output from the delay control circuit 13 in the master DLL circuit 201 and the signal D1-2 output from the delay control signal operation circuit 108 are input to the SEL 111-2. The SEL 111-2 selects one of the signal D0-2 and the signal D102 based on the selection signal SEL and outputs the selected signal as the digital delay control signal q to the slave DLL circuit 102. The selection signal SEL is described in detail below.

The slave delay circuit 102 has the same configuration and operation as the first exemplary embodiment, and therefore the detailed explanations are omitted.

The selection signal SEL is used for selecting one of the signals output by the SEL 111-1 and the SEL 111-2. The selection signal SEL is configured from outside as described below. When the total amount of delay in the digital control delay circuits 105-1 to 105-n is larger than the amount of delay corresponding to the clock cycle of the reference clock RCLK, the selection signal SEL is configured as a signal indicative of selecting and outputting the signals D0-1 and D0-2. Meanwhile, when the total amount of delay in the digital control delay circuits 105-1 to 105-n is smaller than the amount of delay corresponding to the clock cycle of the reference clock RCLK, the selection signal SEL is configured as a signal indicative of selecting and outputting the signals D1-1 and D1-2.

Next, description is given of the operation of the delay locked loop circuit according to this exemplary embodiment when the selection signal SEL is the signal indicative of selecting the signals D0-1 and D0-2. Note that the operation of the delay locked loop circuit when the selection signal SEL is the signal indicative of selecting the signals D1-1 and D1-2 is similar to that of the first exemplary embodiment, so the details description thereof is omitted.

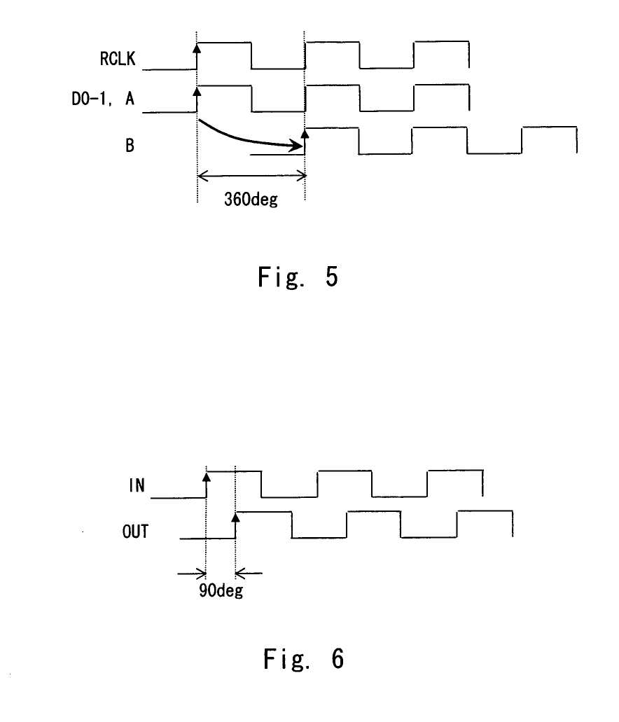

FIG. 5 is the timing chart showing the operation when the signals D0-1 and D0-2 are selected. FIG. 5 shows phase relationships between the reference clock RCLK, the comparison clock signal A of the phase comparison circuit 12, and the comparison clock signal B of the phase comparison circuit 12. The comparison clock signal A is output from the SEL 111-1. The comparison clock signal B is the signal obtained by delaying the signal output from the SEL 111-1 by the master delay part 221. The reference clock RCLK and the signal D0-1 have the same phase. The comparison clock signal B has a 360-degree phase difference from D0-1 and the reference clock RCLK.

In the case of selecting the signals D0-1 and D0-2, the delay control circuit 13 controls the amount of delay of the digital control delay circuits 105-1 to 105-n based on the phase comparison result of the phase comparison circuit 12. The delay control circuit 13 controls the amount of delay so that the comparison clock signal B and the comparison clock signal A have the same phase. That is, the amount of delay in the digital control delay circuits 105-1 to 105-n is controlled to be equal to the amount of delay corresponding to a 360-degree phase.

Here, when the master delay part 221 includes the four digital control circuits 105-1 to 105-4, the amount of delay of each of the digital control circuits105-1 to 105-4 corresponds to the 90-degree phase of the reference clock RCLK. Therefore, the delay control circuit 13 supplies the delay control signal m that has an amount of delay corresponding to the 90-degree phase of the reference clock to the digital control delay circuit 105-1 to 105-4. By supplying the digital control signal m, the total amount of delay of the master delay part 221 equals the amount of delay corresponding to the 360-degree phase of the reference clock RCLK.

The delay control circuit 13 outputs the delay control signal (D0-2) that has the amount of delay corresponding to the 90-degree phase of the reference clock RCLK to the selector SEL 111-2. The SEL 111-2 outputs the signal D0-2 as the digital delay control signal q to the slave delay circuit 102 based on the selection signal SEL.

The slave delay circuit 102 (the first delay circuit) delays the input signal IN based on the digital delay control signal q that has the amount of delay corresponding to the 90-degree phase. The slave delay circuit 102 outputs the delayed signal as the output signal OUT. FIG. 6 shows a phase relationship between each signal when the delay locked loop circuit delays the input signal IN based on the digital delay control signal q that has an amount of delay corresponding to the 90-degree phase.

The operation of the delay locked loop circuit according to this exemplary embodiment will be described by showing a specific example. In this example, assume that the multiplier PLL 107 multiplies the reference clock by 2 (n=2). When the frequency of the multiplied clock is 100 MHz or more, the digital control delay circuits 105-1 to 105-4 must have an amount of delay of 5 ns. The amount of delay of 5 ns corresponds to the 180-degree phase of a signal of 100 MHz. The amount of delay of 5 ns corresponds to the 360-degree phase of a signal of 200 MHz. Therefore, when each of the digital control delay circuits 105-1 to 105-4 has the amount of delay of 5 ns, if the frequency of the reference clock is 200 MHz or more, the digital control delay circuits 105-1 to 105-n can control the amount of delay corresponding to the 360-degree phase.

Assume that the reference clock, in which an increase in phase error needs to be suppressed, has a high frequency band of 200 MHz or more. When the frequency of the reference clock RCLK is 200 MHz or more, the selection signal SEL is configured as a signal indicative of selecting the signals D0-1 and D0-2. By contrast, when the frequency of the reference clock RCLK is 200 MHz or less, the selection signal SEL is configured as a signal indicative of selecting the signals D1-1 and D1-2.

Advantageous effects of the delay locked loop circuit according to this exemplary embodiment will be described below. In the configuration described above, the delay locked loop circuit can select the method of generating an amount of delay based on the frequency of the reference clock RCLK by using the selection signal SEL, the first selection part (SEL 111-1), and the second selection part (SEL 111-2). That is, when the reference clock has a low frequency, the process of generating an amount of delay including a multiplying process can be carried out, because the tolerable amount phase errors is large. By contrast, when the reference clock has a high frequency, the delay locked loop circuit executes the process of generating an amount of delay without the multiplying process, because the tolerable amount of phase errors is small. The process of generating an amount of delay without the multiplying process can reduce phase errors.

Therefore, the delay locked loop circuit can be adapted to a wide frequency range including a high frequency and a low frequency without increasing phase errors when the reference clock has a high frequency. The DLL circuit according to this exemplary embodiment includes the multiplier PLL 107, and thus can be configured with a smaller area than the delay locked loop circuit of the related art.

### Third Exemplary Embodiment

A delay locked loop circuit according to a third exemplary embodiment is characterized by automatically generating the selection signal SEL inside the delay locked loop circuit.

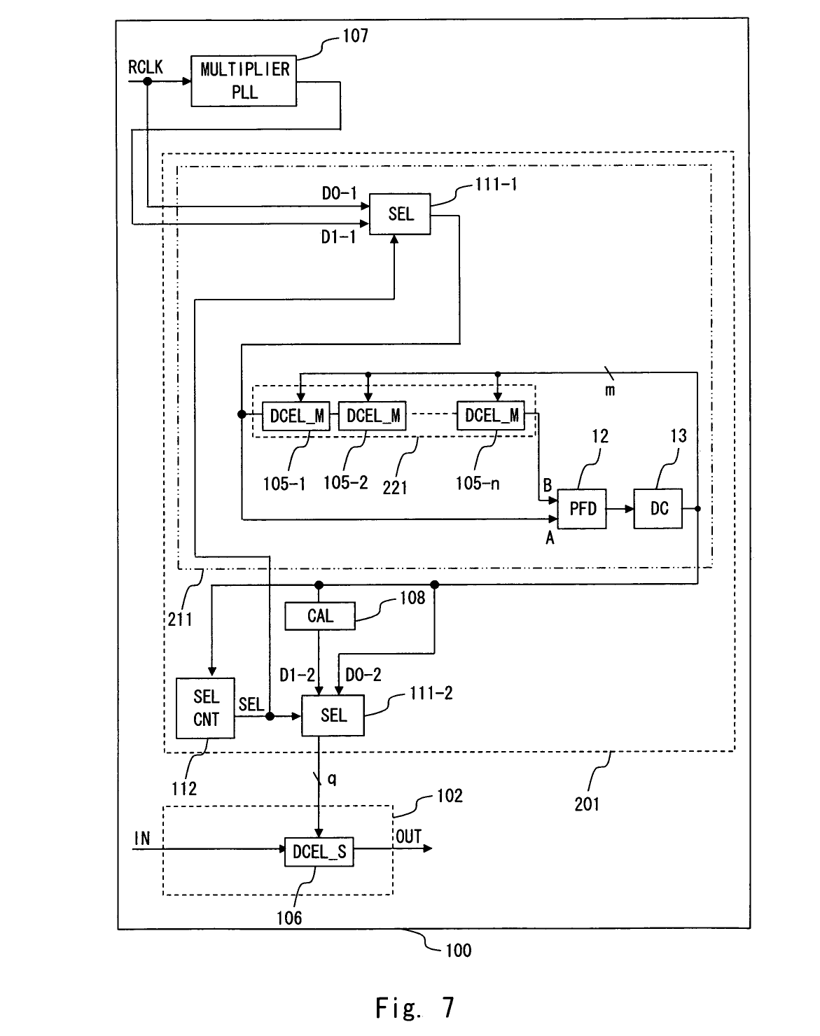

FIG. 7 is a block diagram showing an exemplary configuration of the delay locked loop circuit according to the third exemplary embodiment of the present invention. The delay locked loop circuit includes a selection signal generation circuit 112 that generates the selection signal SEL, in addition to components similar to those of the second exemplary embodiment. Other configurations and operations are the same as those of the second exemplary embodiment. Therefore, the details are omitted. The process of the signal generation circuit 112 is described below.

The delay signal generation circuit 112 receives the delay control signal m from the delay control circuit 13 and outputs the selection signal SEL to the SEL 111-1 and the SEL 111-2.

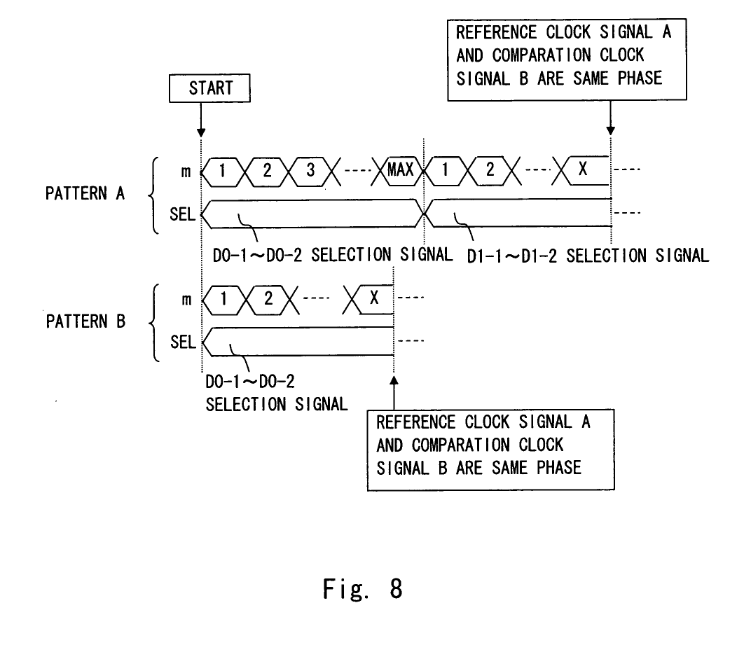

FIG. 8 is the timing chart showing the process of generating the selection signal SEL in the delay signal generation circuit 112. A pattern “A” in FIG. 8 shows the delay control signal m and the selection signal SEL when the total amount of delay in the digital control delay circuits 105-1 to 105-n is smaller than the amount of delay corresponding to the clock cycle of the reference clock RCLK. A pattern “B” in FIG. 8 shows the delay control signal m and the selection signal SEL when the total amount of delay in the digital control delay circuits 105-1 to 105-n is larger than the amount of delay corresponding to the clock cycle of the reference clock RCLK.

The selection signal generation circuit 112 outputs the selection signal SEL for selecting the signals D0-1 and D0-2 in initial condition. The master DLL circuit 201 executes the same process as the second exemplary embodiment. When the delay control signal m indicates a maximum controllable value (“MAX” in FIG. 8), the selection signal generation circuit 112 generates the selection signal SEL to select the signals D1-1 and D1-2. The selection signal generation circuit 112 can be configured using general logic circuits. The operation of the selection generation circuit 112 will be described in detail below.

In the pattern “A” in FIG. 8, the selection signal generation circuit 112 outputs the selection signal SEL to select the signals D0-1 and D0-2 in initial condition. The delay control circuit 13 controls the digital control delay circuits 105-1 to 105-n based on the phase comparison result of the phase comparison circuit 12 so that the comparison clock signal A has the same phase as the comparison clock signal B. However, because the amount of delay in the digital control delay circuits 105-1 to 105-n is smaller than the amount of delay corresponding to the clock cycle of the reference clock RCLK, the comparison clock signal A has a different phase from the comparison clock signal B. In this case, the delay control signal m output by the delay control circuit 13indicates the maximum controllable value (“MAX” in FIG. 8).

When the delay control signal indicates the maximum controllable value (“MAX” in FIG. 8), the delay signal generation circuit 112 outputs the signal as the selection signal SEL to select the signals D1-1 and D1-2.

The subsequent process is similar to that shown in the second exemplary embodiment. The delay control circuit 13 controls the amount of delay in the digital control delay circuits 105-1 to 105-n so that the comparison clock signal A input to the phase comparison circuit 12 has the same phase as the comparison clock signal B input to the phase comparison circuit 12.

Next, the process shown in the pattern “A” of FIG. 8 will be described. The selection signal generation circuit 112 outputs the selection signal SEL to select the signals D0-1 and D0-2 in initial condition. The delay control circuit 13 controls the digital control delay circuits 105-1 to 105-n based on the phase comparison result of the phase comparison circuit 12 so that the comparison clock signal A has the same phase as the comparison clock signal B. In this case, because the amount of delay in the digital control delay circuits 105-1 to 105-n is larger than the amount of delay corresponding to the clock cycle of the reference clock RCLK, the delay control circuit 13 controls the digital control delay circuits so that the comparison clock signal A has the same phase as the comparison clock signal B. That is, the delay control signal m output by the delay control circuit 13 indicates a value equal to or smaller than the maximum controllable value.

When the value of the delay control signal m is equal to or smaller than the maximum controllable value, the delay signal generation circuit 112 generates and outputs the selection signal for selecting the signals D0-1 and D0-2.

By the above series of processes, the delay locked loop circuit can automatically generate the selection signal SEL in the delay locked loop circuit, compared to the second exemplary embodiment. This is because the delay signal generation circuit 112 generates the selection signal SEL based on the delay control signal m in the delay locked loop circuit. This eliminates the need to input the selection signal SEL from outside.

Similar to the second exemplary embodiment, even when the reference clock RCLK has a high frequency, the delay locked loop circuit can be adapted to a wide frequency range including a high frequency and a low frequency without increasing phase errors. Further, similar to the first and second exemplary embodiments of the present invention, the DLL circuit according to this exemplary embodiment includes the multiplier PLL 107, and thus can be configured with a small area, compared to the DLL circuit of the related art.

### Fourth Exemplary Embodiment

A delay locked loop circuit according to a fourth exemplary embodiment can implement the same process as that of the delay locked loop circuit according to the first exemplary embodiment, using a configuration different from that of the first exemplary embodiment.

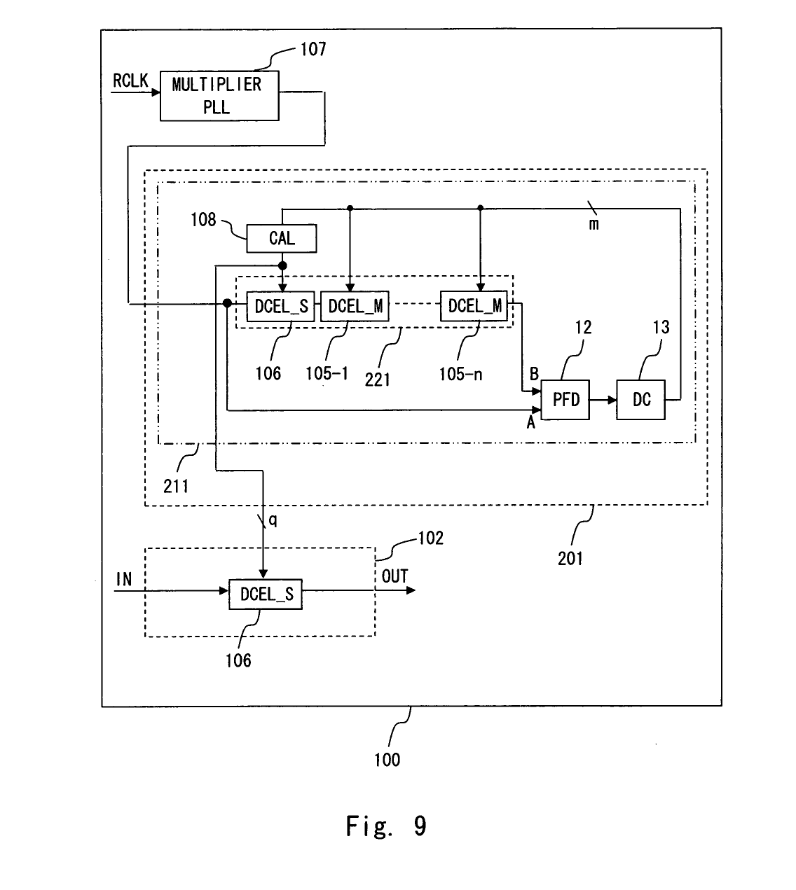

FIG. 9 is a block diagram showing an exemplary configuration of the delay locked loop circuit according to this exemplary embodiment. In this exemplary embodiment, the master delay part 221 in the master DLL part 211 includes the digital control delay circuits 105-1 to 105-n and the digital control delay circuit 106. The digital control delay circuit 106 in the master delay part 221 has the same configuration as the digital control delay circuit 106 in the slave delay circuit 102.

The delay control circuit 13 outputs the delay control signal m to the digital control delay circuits 105-1 to 105-n and the delay control signal operation circuit 108. The delay control signal operation circuit 108 performs an operation based on the delay control signal m. The delay control signal operation circuit 108 outputs the digital delay control signal q generated based on the operation result to the digital control delay circuit 106 in the master delay part 221, and to the digital control delay circuit 106 in the slave delay circuit 102. Other configurations of the delay locked loop circuit are similar to those of the first exemplary embodiment. Therefore, the description of the other configurations is omitted.

Next, description is given of the operation of the delay locked loop circuit when the multiplier PLL 107 multiplies the clock by 2.

The multiplier PLL 107 outputs the clock signal which is twice as fast as the reference clock RCLK to the master delay part 221 and the phase comparison circuit 12. The phase comparison circuit 12 is supplied with the clock signal, which is input to the master delay part 221, through the digital delay circuit 106 and the digital control delay circuits 105-1 to 105-n.

The phase comparison circuit 12 compares a phase of the comparison signal A with a phase of the comparison signal B, and outputs the phase comparison result to the delay control circuit 13. The phase comparison circuit 12 compares the phases in accordance with the comparison signal A as shown in FIG. 2.

The delay control circuit 13 controls the digital control delay circuits 105-1 to 105-n and the digital control delay circuit 106 so that the comparison clock signal A has the same phase as the comparison clock signal B based on the phase comparison result of the phase comparison circuit 12.

A description is given of an exemplary operation of the delay locked loop circuit when the input signal IN, which is input to the slave delay circuit 102, is delayed by an amount corresponding to the 90-degree phase of the reference clock RCLK and output as the output signal OUT. The master delay part 221 includes the digital control delay circuit 106, the digital control delay circuit 105-1, and the digital control delay circuit 105-2.

In the delay locked loop circuit according to this exemplary embodiment, the amount of delay with respect to the input signal IN, and a ratio of the amount of delay in the digital control delay circuit 106 in the master delay part 221 to the amount of delay in the digital control delay circuit 105-n are predetermined.

In this configuration, a case is described in which the input signal IN is delayed by an amount of delay corresponding to the 90-degree phase of the reference clock. In this case, the digital control delay circuit 106 in the master delay part 221 has an amount of delay that is twice the amount of delay in the digital control delay circuit 105-n.

The multiplier PLL 107 multiplies the reference clock RCLK by 2. Thus, the master delay part 222 needs to have the amount of delay corresponding to a 180-degree phase of the reference clock.

In this case, each of the digital control delay circuits 105-1 and 105-2 has the amount of delay corresponding to a 45-degree phase of the reference clock RCLK. The delay control signal operation circuit 108 multiplies the delay control signal m, which has an amount of delay corresponding to a 45-degree phase of the reference clock, by 2. The digital control delay circuit 106 in the master delay part 221 has the amount of delay corresponding to a 90-degree phase of the reference clock RCLK. The master delay part 221 has the amount of delay corresponding to a 180-degree phase of the reference clock RCLK. This amount of delay in the master delay part 221 equals the total amount of delay of the digital control delay circuit 106 and the digital control delay circuits 105-1 and 105-2.

The delay control signal operation circuit 108 outputs the digital delay control signal q that is obtained by multiplying the delay control signal m, which has an amount of delay corresponding to the 45-degree phase of the reference clock RCLK, by 2 to the slave delay circuit 102. The slave delay circuit 102 delays the input signal IN and outputs the output signal OUT that has an amount of delay corresponding to a 90-degree phase of the reference clock RCLK.

By the above series of processes, the delay locked loop circuit having the same operations and effects as those of the first exemplary embodiment can be achieved. That is, it is possible to provide the delay locked loop circuit capable of preventing an increase in the area of the DLL circuit.

The present invention is not limited to the above exemplary embodiments, and can be modified in various ways without departing from the scope of the present invention.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

The first to fourth exemplary embodiments can be combined as desirable by one of ordinary skill in the art.

What is claimed is:

1. A delay locked loop circuit comprising:
a multiplier PLL (Phase Lock Loop) that multiplies a reference clock and outputs the multiplied reference clock;
a DLL (Delay Locked Loop) that applies an amount of delay corresponding to a given cycle to the clock output from the multiplier PLL to generate a delay signal having a given amount of delay so that the delay signal has the same phase as the clock output from the multiplier PLL;
a delay control signal operation circuit that generates a delay control signal having a given amount of delay based on the delay signal having the given amount of delay; and
a first delay circuit that delays an input signal based on the delay control signal.

2. The delay locked loop circuit according to claim 1, wherein
the DLL includes a second delay circuit that applies a delay corresponding to a given cycle to the clock output by the multiplier PLL, and
the first and second delay circuits include one or more delay elements having substantially the same configuration.

3. The delay locked loop circuit according to claim 1, wherein
the DLL includes a phase comparison circuit that compares a phase of the clock output from the multiplier PLL with a phase of a delayed clock output from the multiplier PLL; and a delay control circuit that generates a delay signal based on a comparison result of the phase comparison circuit.

4. The delay locked loop circuit according to claim 2, wherein
the first delay circuit includes a circuit that is substantially the same as the second delay circuit, and
the delay control signal operation circuit controls the first delay circuit and the second delay circuit by supplying the delay control signal to the first delay circuit and the DLL.

5. The delay locked loop circuit according to claim 1, further comprising:
a first selection part that selects one of the clock output from the multiplier PLL and the reference clock based on a selection signal, and outputs a selected clock to the DLL; and
a second selection part that selects one of the delay signal and the delay control signal based on the selection signal, and outputs a selected signal to the first delay circuit,
wherein the DLL generates the delay signal by applying an amount of delay corresponding to the given cycle to the signal output from the first selection part so that the delay signal has the same phase as the signal output from the first selection part, and
the first delay circuit delays an input signal based on the signal output from the second selection part.

6. The delay locked loop circuit according to claim 5, further comprising:
a selection signal generation circuit that compares an amount of delay of the clock by the DLL with an amount of delay corresponding to a clock cycle of the reference clock, and generates the selection signal for the first selection part to select the clock output from the multiplier PLL and for the second selection part to select the delay control signal when the amount of delay of the clock by the DLL is smaller than an amount of delay corresponding to a clock cycle of the reference clock, and generates the selection signal for the first selection part to select the reference clock and for the second selection part to select the delay signal when the amount of delay of the clock by the DLL is larger than the amount of delay corresponding to a clock cycle of the reference clock.

7. An LSI device comprising the delay locked loop circuit according to claim 1.

8. A signal delay method comprising:
multiplying a reference clock by a multiplier PLL and applying an amount of delay corresponding to a given cycle of the multiplied clock output from the multiplier PLL so that a delayed signal has the same phase as the clock multiplied by the multiplier PLL;
generating a delay signal having a given amount of delay based on the amount of delay corresponding to the given cycle of the multiplied clock;
generating a delay control signal based on the delay signal having the given amount of delay; and
delaying an input signal based on the delay control signal.
